(19) United States
(12) Patent Application Publication
(10) Pub. No.: US 2007/0178623 A1
(43) Pub. Date: Aug. 2, 2007

(54) Method of manufacturing semiconductor device

(75) Inventors: Hirohisa Shimokawa, Tokyo (JP); Naoki Izumi, Tokyo (JP)

Correspondence Address: MCDERMOTT WILL & EMERY LLP, 600 13TH STREET, N.W., WASHINGTON, DC, 20005-3096, US

(73) Assignee: RENESAS TECHNOLOGY CORP.

(21) Appl. No.: 11/699,568

(22) Filed: Jan. 30, 2007

(30) Foreign Application Priority Data
Jan. 30, 2006 (JP) 2006-021029

(51) Int. Cl. H01L 21/00

(52) U.S. Cl. 438/106

(57) ABSTRACT

A method of manufacturing a semiconductor device includes a bonding step of bonding a chip on a wiring board by means of a bonding layer, and a wire bonding step of bonding a wire to a pad on the chip while applying ultrasonic vibration after the bonding step. A material having an elastic modulus of 100 MPa or higher at a process temperature in the wire bonding step is used as the bonding layer.

### BACKGROUND OF THE INVENTION

1. Field of the Invention

The present invention relates to a method of manufacturing a semiconductor device by bonding a chip on a wiring board by means of a bonding layer and thereafter bonding wires to pads on the chip while applying ultrasonic vibration.

2. Background Art

A bonding layer in the form of a film is used at the time of bonding of a chip on a lead frame or a wiring board (see, for example, Japanese Patent Laid-Open No. 2003-119440). In the case of use of such a bonding layer on a wiring board, a gap is formed between the bonding layer and the wiring board because protrusions/recesses having a height/depth of 5 to 20 μm exist in the surface of the wiring board. If the bonding layer is soft, air in the gap is expelled by the pressure at the time of resin encapsulation and there is, therefore, no problem with such protrusions/recesses. If the bonding layer is hard, it is difficult to expel air from the gap and air can remain by forming voids to act as a cause of breakage of the chip, for example, by heat at the time of mounting in a package. Conventionally, therefore, a material having an elastic modulus of 10 MPa or less at the process temperature in the wire bonding step is used as the bonding layer.

After bonding of the chip on the wiring board by means of the bonding layer, wires are bonded to pads on the chip. At this time, ultrasonic vibration is applied to break an oxide film on the pad surface, thereby increasing the strength of junction between the pads and the wires.

In recent years, chips having a chip size of a 3×3 mm square or smaller have been put to use in a microcomputers of 4 to 16 bits or the like. The area of bonding between such a chip and a wiring board is small and the strength of junction between the chip and the wiring board is also small. Therefore, the chip vibrates with ultrasonic vibration in the wire bonding step, so that the oxide film on the pad surface cannot be sufficiently broken and the strength of junction between the pads and the wires is reduced.

### SUMMARY OF THE INVENTION

In view of the above-described problem, an object of the present invention is to provide a semiconductor device manufacturing method which makes it possible to increase the strength of junction between pads on a chip and wires.

According to one aspect of the present invention, a method of manufacturing a semiconductor device includes a bonding step of bonding a chip on a wiring board by means of a bonding layer, and a wire bonding step of bonding a wire to a pad on the chip while applying ultrasonic vibration after the bonding step. A material having an elastic modulus of 100 MPa or higher at a process temperature in the wire bonding step is used as the bonding layer.

According to the present invention, vibration of the chip with ultrasonic vibration in the wire bonding step can be limited to increase the strength of junction between the pad on the chip and the wire.

Other and further objects, features and advantages of the invention will appear more fully from the following description.

### BRIEF DESCRIPTION OF THE DRAWINGS

FIG. 1 is a plan view of a wiring board showing the entire appearance of the wiring board;

FIG. 2 is a plan view of the wiring board;

FIG. 3 is a sectional view of the wiring board;

FIG. 4 is an enlarged sectional view of an essential portion of the wiring board shown in FIG. 3;

FIG. 5 is a plan view showing the process of manufacturing a semiconductor device according to an embodiment of the present invention;

FIG. 6 is a sectional view showing the process of manufacturing the semiconductor device according to the embodiment of the present invention;

FIG. 7 is an enlarged sectional view of an essential portion of the semiconductor device shown in FIG. 6;

FIG. 8 is a plan view showing the process of manufacturing the semiconductor device according to the embodiment of the present invention;

FIG. 9 is a sectional view showing the process of manufacturing the semiconductor device according to the embodiment of the present invention;

FIG. 10 is a sectional view showing a wire bonding step;

FIG. 11 is a plan view showing the process of manufacturing the semiconductor device according to the embodiment of the present invention;

FIG. 12 is a sectional view showing the process of manufacturing the semiconductor device according to the embodiment of the present invention;

FIG. 13 is a plan view showing the process of manufacturing the semiconductor device according to the embodiment of the present invention;

FIG. 14 is a sectional view showing the process of manufacturing the semiconductor device according to the embodiment of the present invention;

FIG. 15 is a plan view showing the process of manufacturing the semiconductor device according to the embodiment of the present invention;

FIG. 16 is a sectional view showing the process of manufacturing the semiconductor device according to the embodiment of the present invention;

FIG. 17 is a sectional view showing the process of manufacturing the semiconductor device according to the embodiment of the present invention;

FIG. 18 is an enlarged sectional view of an essential portion of the semiconductor device shown in FIG. 17; and

FIG. 19 is a plan view showing a wiring board in which the proportion of portions where Cu wiring exists in the surface area for bonding of the chip is 90% or more.

### DETAILED DESCRIPTION OF THE PREFERRED EMBODIMENTS

### First Embodiment

A method of manufacturing a semiconductor device according to an embodiment of the present invention will be described with reference to the accompanying drawings.

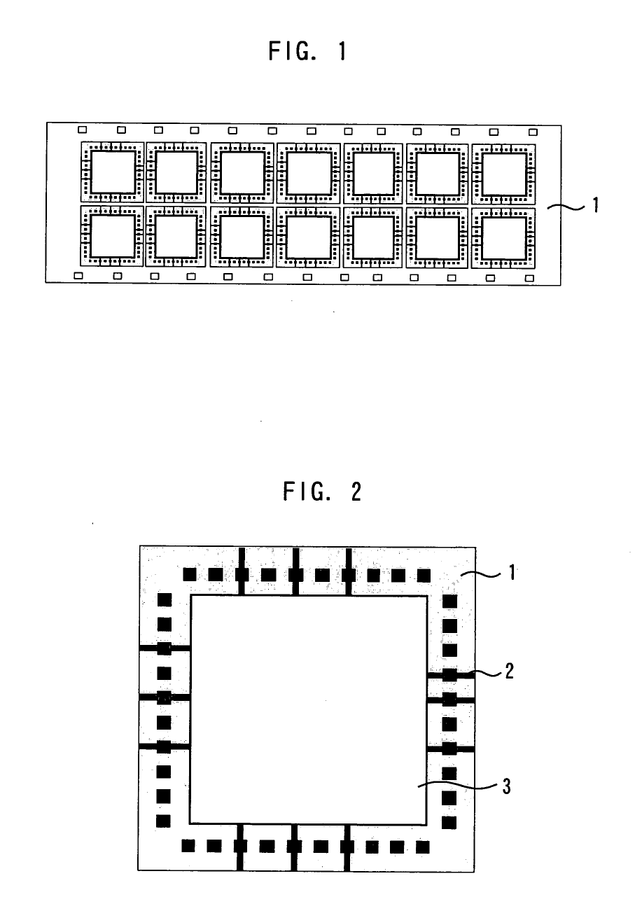

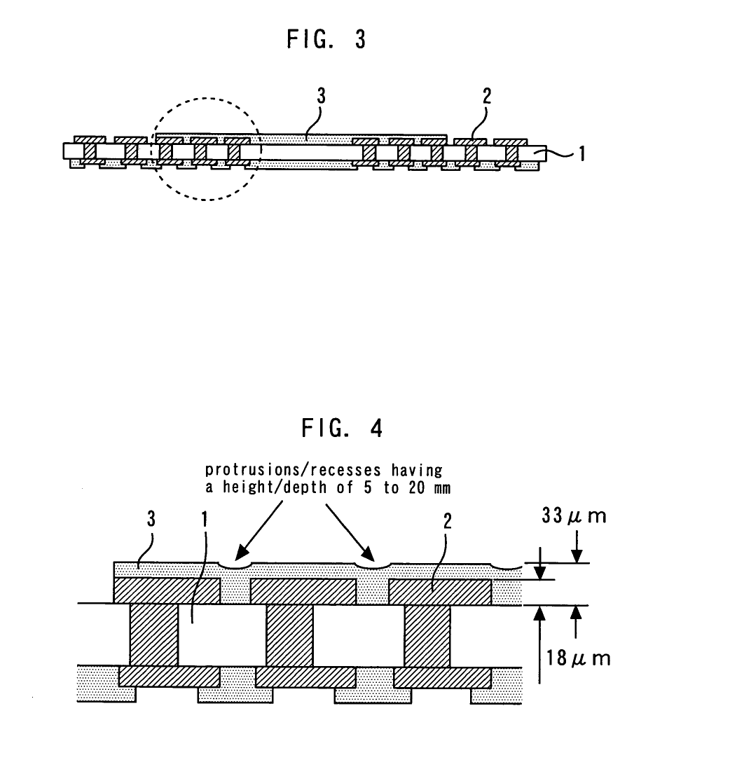

A wiring board 1 such as shown in FIG. 1 is prepared. A plurality of structural units each constructed as shown in FIG. 2 are arranged on the wiring board 1. FIG. 3 is a sectional view of the wiring board. As illustrated, a plurality of Cu wiring elements 2 are provided on the wiring board 1, and the surfaces of portions of the wiring board 1 are covered with a solder resist 3.

FIG. 4 is an enlarged sectional view of an essential portion of the wiring board. The thickness of the Cu wiring elements 2 on the wiring board 1 is 18 μm and the total of the thicknesses of the Cu wiring elements 2 and the solder resist 3 is 33 μm. The solder resist 3 between the Cu wiring elements 2 dents, so that protrusions/recesses having a height/depth of 5 to 20 μm are formed in the surface of the solder resist 3.

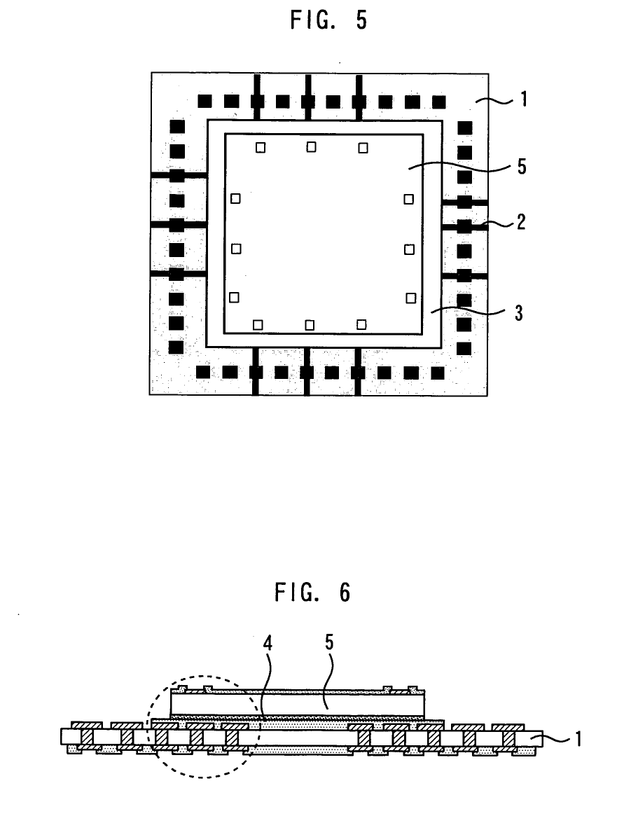

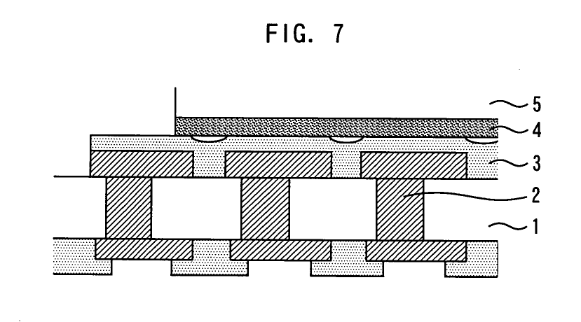

As shown in FIGS. 5 and 6, a 3 mm-square chip 5 is bonded on the wiring board 1, with a bonding layer 4 interposed therebetween. A material having an elastic modulus of 100 MPa or more at the process temperature in a wire bonding step described below is used as the bonding layer 4. Because of use of the bonding layer 4 having such a high elastic modulus, a small gap is formed between the solder resist 3 and the bonding layer 4, as shown in FIG. 7. The thickness of the bonding layer 4 is set to 25 μm or less to limit the thickness of the semiconductor device.

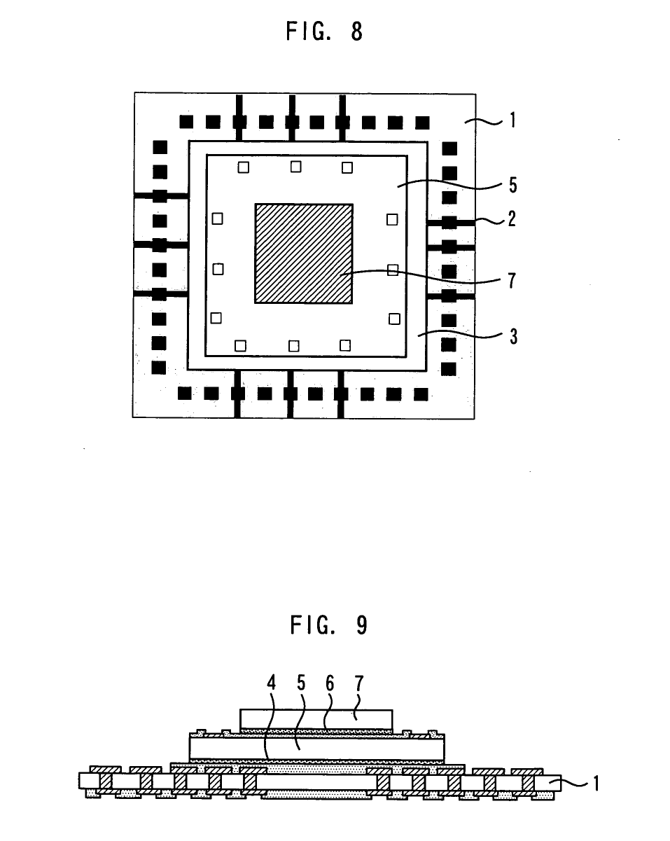

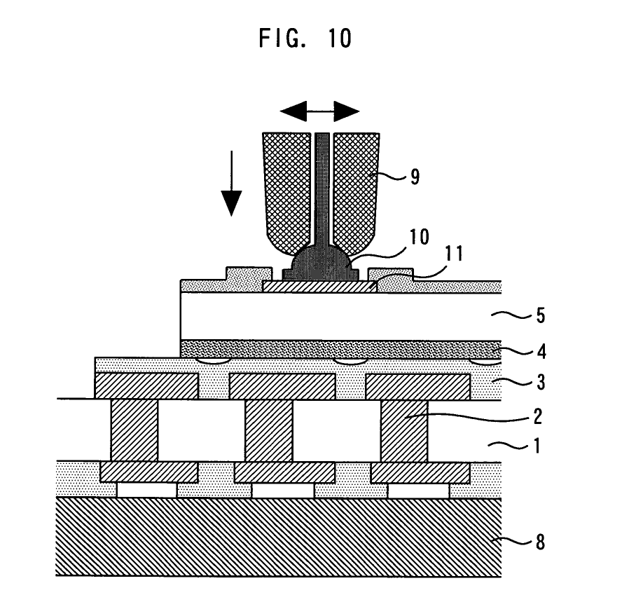

Subsequently, as shown in FIGS. 8 and 9, a 2 mm-square spacer chip 7 is mounted on the chip 5, with a bonding layer 6 interposed therebetween. The bonding layer 6 is formed of the same material as that of the bonding layer 4.

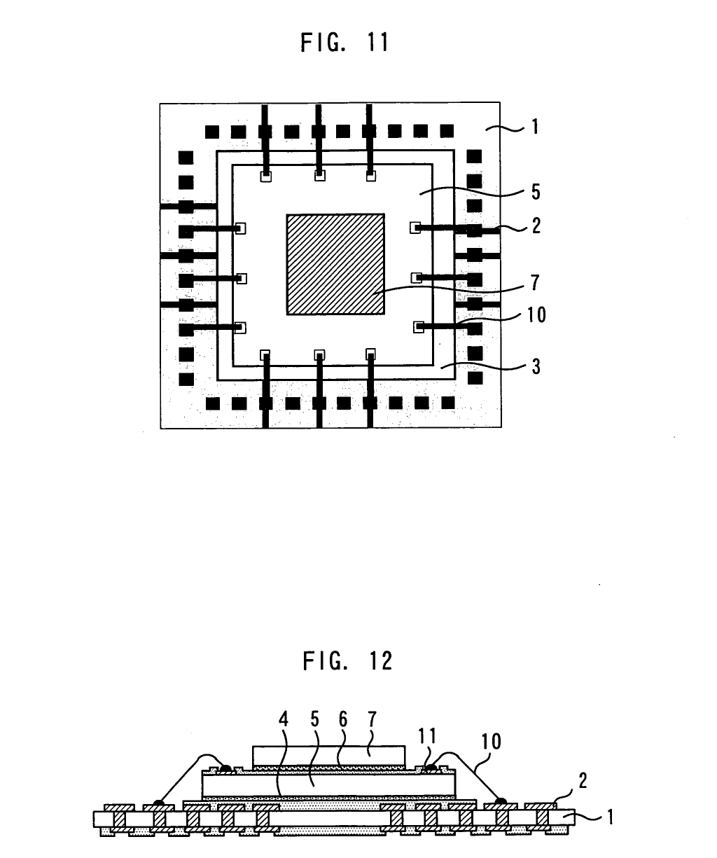

Subsequently, the wiring board 1 is placed on a stage 8, as shown in FIG. 10. A gold wire 10 fed from a capillary 9 is then bonded to a pad 11 on the chip 5 by pressing a gold ball on an end of the gold wire 10 against the pad 11 while applying ultrasonic vibration from the capillary 9 to the ball. The load from the capillary 9 for this pressing is 20 to 80 g, the amplitude of ultrasonic vibration is about 1 μm, and the frequency of ultrasonic vibration is 60 to 120 kHz. The other end of the gold wire 10 is bonded to the wiring element 2 on the wiring board 1, as shown in FIGS. 11 and 12.

As described above, a material having an elastic modulus of 100 MPa or more at the process temperature in the wire bonding step is used as the bonding layer 4 to limit vibration of the chip 5 with ultrasonic vibration in the wire bonding step and to thereby improve the strength of junction between the pad 11 on the chip 5 and the gold wire 10.

This effect is high even in a case where a chip having a chip size of a 3 mm square or smaller is used as the chip 5. In the case of using such a small chip, air can be easily expelled from the gap between the bonding layer 4 and the wiring board 1 even if the bonding layer 4 has a high elastic modulus. A similar effect is also ensured with respect to a case where a chip having a shorter-side length of 3 mm or less or a chip having an area of 9 mm² or less is used as the chip 5.

The process temperature in the wire bonding step is set to preferably 100° C. or higher, more preferably 150° C. or higher to ensure the desired strength of junction between the pad 11 on the chip 5 and the gold wire 10. More specifically, the temperature of the stage 8 on which the wiring board 1 is placed is set to 160° C. to supply heat to the chip 5 side.

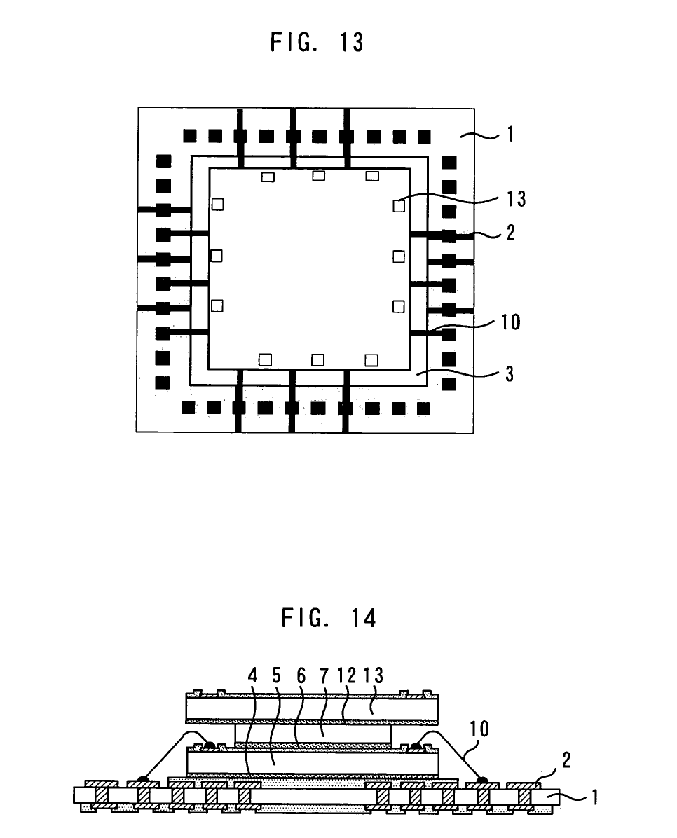

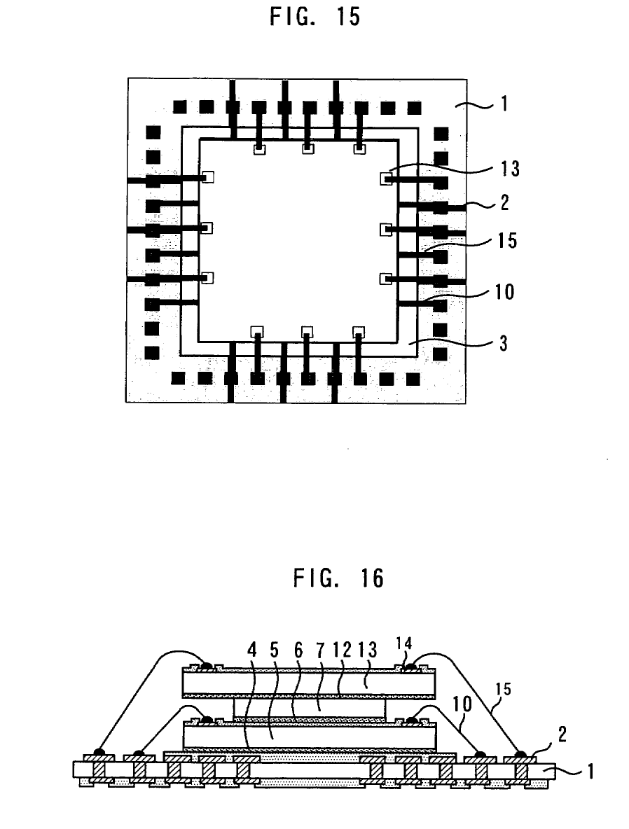

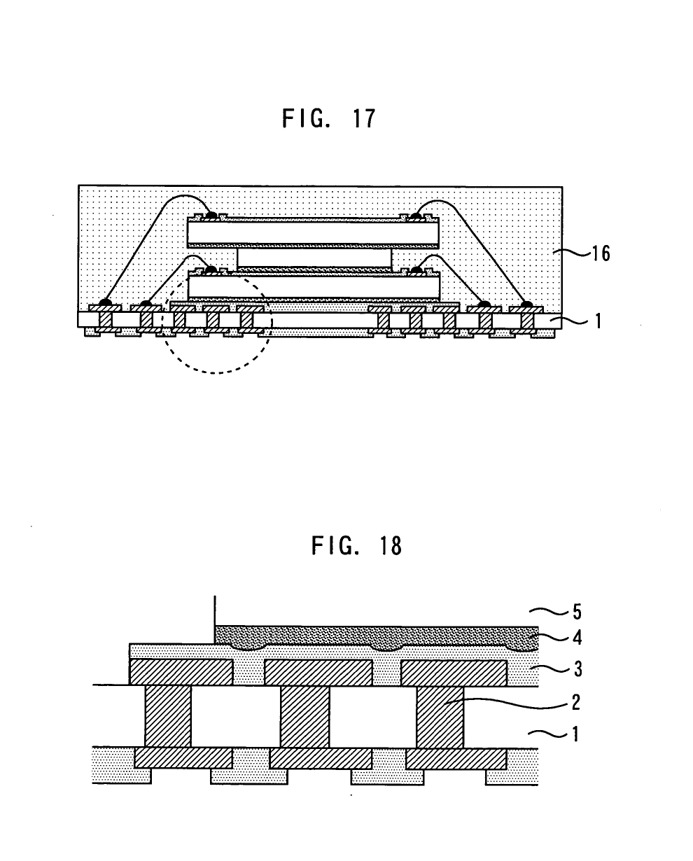

Subsequently, as shown in FIGS. 13 and 14, a 3 mm-square chip 13 is mounted on a spacer chip 7, with a bonding layer 12 interposed therebetween. The bonding layer 12 is formed of the same material as that of the bonding layer 4. As shown in FIGS. 15 and 16, a wire 15 is bonded to a pad 14 on the chip 13 and to the Cu wiring element 2 on the wiring board 1 in the same manner as described above.

Subsequently, as shown in FIG. 17, the chips on the wiring board 1 are encapsulated in a resin 16 by a transfer molding method. The pressure at which the resin is injected is set to 8 MPa or higher. By the pressure at the time of resin injection, air can be expelled from the gap between the bonding layer 4 and the wiring board 1, as shown in FIG. 18. The resin 16 is formed of a thermosetting epoxy resin or the like. The transfer molding step temperature is, for example, 180° C. Preferably, the elastic modulus of the bonding layer 4 is equal to or lower than a certain value, because if the elastic modulus is excessively high the deformation of the bonding layer 4 for conformation to protrusions/recesses in the surface of the wiring board 1 does not progress sufficiently when the bonding layer 4 receives the pressure from the resin during transfer molding. More specifically, the elastic modulus of the bonding layer 4 at the transfer molding step temperature is preferably 1 GPa or less. In particular, in a case where the thickness of the bonding layer 4 is limited to 25 μm or less to enable the semiconductor device to have a reduced thickness, selection of the bonding layer 4 having a suitable elastic modulus is important. The semiconductor device according to the embodiment of the present invention is manufactured by the above-described process.

If a material in the form of a paste is used as the bonding layer 4, there is a problem that the bonding layer 4 can easily protrude from the region between the chip 5 and the wiring board 1. In particular, in a case where the distance between the ends of the chip 5 and the Cu wiring elements 2 on the wiring board 1 is set to 0.5 mm or less, the protruding bonding layer 4 may reach the Cu wiring elements 2 on the wiring board 1 to cause a fault. Also, in a case where a chip having a thickness of 100 μm or less is used as the chip 5, the protruding bonding layer 4 may rise and reach the upper surface of the chip 5 to cause a fault. Preferably, a material in the form of a film is used as the bonding layer 4.

In a case where the bonding layer 4 in the form of a film is used, a wafer on which a plurality of chips 5 are formed may be cut between each adjacent pair of chips 5 after attachment of the bonding layer 4 to the back surface of the wafer. The manufacturing process can be simplified in this way. As the bonding layer 4, a material containing 10 wt % or higher, preferably 50 at % or higher of an inorganic filler such as a silica filler or a BN filler to increase the elastic modulus is used.

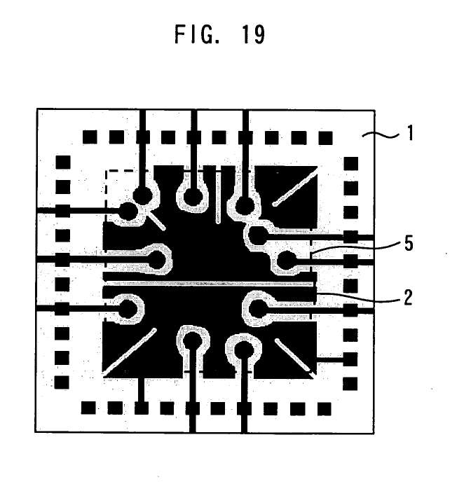

If air remains in a gap between a recess in the surface of the wiring board 1 and the chip, it forms a void. Prevention of breakage of the chip 5 due such a void requires setting the proportion of voids under the chip 5 in the final form to 10% or less. As the wiring board 1, therefore, a wiring board having 90% or more of portion where the Cu wiring elements 2 exist in the surface area for bonding to the chip 5, as shown in FIG. 19, is used. Preferably, with respect to wiring in the region where the chip 5 is bonded, the region is adjusted by setting the width of dummy wiring pattern elements at a floating potential and the width of power supply/GND wiring pattern elements connected to electrodes at power supply potential or ground potential larger than the width of signal wiring elements. The signal wiring elements may be formed so as to be thinner than these large-width wiring elements and generally uniform to prevent, for example, the formation of a noise source due to the formation of stub wiring or impedance mismatching. The configuration of the large-width wiring pattern in the region below the chip is preferably such that radial slits continued to the region outside the chip are formed, as shown in FIG. 19. The formation of radial slits continued to the region outside the chip ensures that voids remaining under the chip can be efficiently expelled to the outside of the chip.

As the wiring board 1, a wiring board in which the height or depth of projections/recesses in the surfaces is 10 μm or less, more preferably 2 μm or less may be used to enable the bonding layer 4 to enter the recesses in the surface of the wiring board 1 more easily and to thereby further increase the strength of junction between the chip 5 and the wiring board 1. As a means for reducing the height/depth of projections/recesses in the wiring board 1 surface, a certain method, e.g., a method of applying a solder resist in two separate layers or a method of using a dry film resist and forming the film by thermocompression with a lamination roller can be selected.

Obviously many modifications and variations of the present invention are possible in the light of the above teachings. It is therefore to be understood that within the scope of the appended claims the invention may be practiced otherwise than as specifically described.

The entire disclosure of a Japanese Patent Application No. 2006-021029, filed on Jan. 30, 2006 including specification, claims, drawings and summary, on which the Convention priority of the present application is based, are incorporated herein by reference in its entirety.

What is claimed is:

1. A method of manufacturing a semiconductor device comprising;
a bonding step of bonding a chip on a wiring board by means of a bonding layer; and
a wire bonding step of bonding a wire to a pad on the chip while applying ultrasonic vibration after the bonding step,
wherein a material having an elastic modulus of 100 MPa or higher at a process temperature in the wire bonding step is used as the bonding layer.

2. The method according to claim 1, wherein the chip used has a chip size of a 3 mm square or smaller.

3. The method according to claim 1, wherein the shorter side of the chip used has a length of 3 mm or less.

4. The method according to claim 1, wherein the chip used has an area of 9 mm² or less.

5. The method according to claim 1, wherein the process temperature in the wire bonding step is set to 100° C. or higher.

6. The method according to claim 1, wherein the process temperature in the wire bonding step is set to 150° C. or higher.

7. The method according to claim 1, further comprising a resin encapsulation step of performing resin encapsulation on the wiring board by transfer molding after the wire bonding step.

8. The method according to claim 7, wherein in the resin encapsulation step the pressure at the time of resin encapsulation is 8 MPa or higher.

9. The method according to claim 1, wherein a film is used as the bonding layer.

10. The method according to claim 9, wherein the distance between ends of the chip and wiring on the wiring board is 0.5 mm or less.

11. The method according to claim 9, wherein the chip used has a thickness of 100 μm or less.

12. The method according to claim 9, further comprising a step of, after attaching the bonding layer to a back surface of a wafer on which a plurality of the chips are formed, cutting the wafer between each adjacent pair of the chips.

13. The method according to claim 9, wherein a material containing 10 wt % or more of an inorganic filler is used as the bonding layer.

14. The method according to claim 9, wherein a material containing 50 wt % or more of an inorganic filler is used as the bonding layer.

15. The method according to claim 1, wherein a wiring board in which the proportion of portions where wiring exists in the surface area for bonding of the chip is 90% or more is used as the wiring board.

16. The method according to claim 1, wherein a wiring board in which the height/depth of protrusions/recesses in the surface is 2 μm or less is used as the wiring board.

17. The method according to claim 1, wherein a wiring board in which the height/depth of protrusions/recesses in the surface is 10 μm or less is used as the wiring board.

18. The method according to claim 1,
further comprising a resin encapsulation step of performing resin encapsulation on the wiring board by transfer molding after the wire bonding step
wherein a material having an elastic modulus of 1 GPa or less at the process temperature in the transfer molding is used as the bonding layer.
